(19) United States
(12) Patent Application Publication
(10) Pub. No.: US 2013/0149817 A1
(43) Pub. Date: Jun. 13, 2013

(54) FABRICATING METHODS OF SEMICONDUCTOR DEVICES AND PICK-UP APPARATUSES OF SEMICONDUCTOR DEVICES THEREIN

(71) Applicants: Chang-Seong JEON, Hwaseong-si (KR); Sang-Sick PARK, Seoul (KR); Sang-Wook PARK, Hwaseong-si (KR); Teak-Hoon LEE, Hwaseong-si (KR); Kwang-Chul CHOI, Suwon-si (KR)

(72) Inventors: Chang-Seong JEON, Hwaseong-si (KR); Sang-Sick PARK, Seoul (KR); Sang-Wook PARK, Hwaseong-si (KR); Teak-Hoon LEE, Hwaseong-si (KR); Kwang-Chul CHOI, Suwon-si (KR)

(73) Assignee: SAMSUNG ELECTRONICS CO., LTD., Suwon-si (KR)

(21) Appl. No.: 13/559,141

(22) Filed: Jul. 26, 2012

(30) Foreign Application Priority Data
Dec. 12, 2011 (KR) 10-2011-0132977

(51) Int. Cl. H01L 21/762

(52) U.S. Cl. 438/118; 257/E21.567

(57) ABSTRACT

A fabricating method of a semiconductor device may include forming a semiconductor die on a supporting wafer, and picking up the die from the wafer by attaching to the die a transfer unit, the transfer unit including a head unit configured to enable twisting movement, and performing the twisting movement. A fabricating method of a semiconductor device may include forming a first semiconductor device on a supporting wafer; and picking up the first semiconductor device from the wafer, moving the first semiconductor device onto a second semiconductor device, and bonding the first semiconductor device to the second semiconductor device while maintaining the first semiconductor device oriented so that a surface faces upwardly. A fabricating method of a semiconductor device may include forming a first semiconductor device on a supporting wafer, attaching to the first semiconductor device a transfer unit configured to enable twisting movement, and performing the twisting movement.

### CROSS-REFERENCE TO RELATED APPLICATION(S)

This application claims priority from Korean Patent Application No. 10-2011-0132977 filed on Dec. 12, 2011, in the Korean Intellectual Property Office (KIPO), the entire contents of which are incorporated herein by reference.

### BACKGROUND

1. Field of the Invention

Example embodiments may relate to fabricating methods of semiconductor devices. Example embodiments also may relate to pick-up apparatuses for the semiconductor devices used therein.

2. Description of the Related Art

With the recent tendency for high performance and high speed memory devices, flip chip packages are drawing attention. The flip chip package is faster in operation and has better power consumption efficiency than a wire bonding package. In addition, a chip level stack has recently been enabled by using a through-silicon via (TSV) method, thereby fabricating a package having multiple flip chips stacked.

In order to fabricate a package having multiple flip chips stacked, a process of picking up a semiconductor chip is required. However, a supporting wafer for supporting a wafer thinned in the course of fabricating flip chips is required, and before picking up the semiconductor chip, the supporting wafer is removed.

Since a thin semiconductor chip having TSV is subjected to severer warpage and weaker in mechanical strength than a thick semiconductor chip, it is prone to damages. Therefore, after removing a supporting wafer from the semiconductor chip, a pick-up process using a transfer unit is required. In addition, in order to facilitate the pick-up process, a push-up unit is employed.

### SUMMARY

Example embodiments may provide fabricating methods of semiconductor devices that may be able to directly pick up semiconductor devices from supporting wafers without using a push-up unit without removing the supporting wafer and performs picking up, carrying and bonding by using a single transfer unit.

Example embodiments also may provide pick-up apparatuses for semiconductor devices that may be able to pick up the semiconductor devices from supporting wafers to enable twisting movement without using a push-up unit while performing carrying and bonding of the semiconductor device.

In some example embodiments, a fabricating method of a semiconductor device may include forming a semiconductor die on a supporting wafer; picking up the semiconductor die from the supporting wafer by attaching to the semiconductor die a transfer unit, the transfer unit including a head unit configured to enable twisting movement, and/or performing the twisting movement.

In some example embodiments, after the semiconductor die is picked up from the supporting wafer, the semiconductor die may be moved to a top portion of a first semiconductor device by using the twisting movement, and/or the semiconductor die may be bonded to the first semiconductor device.

In some example embodiments, the twisting movement may include performing circular arc exercise on the semiconductor die by using the transfer unit.

In some example embodiments, picking up the semiconductor die from the supporting wafer may include picking up the semiconductor die by using the transfer unit after separating an edge of the semiconductor die from the supporting wafer by performing circular arc exercise on the semiconductor die.

In some example embodiments, the twisting movement may further include separating one edge of the semiconductor die from the supporting wafer by performing circular arc exercise on the semiconductor die by using the transfer unit at an angle of θθ0 with respect to a first direction perpendicular to a second direction from the transfer unit to the semiconductor die, and/or separating another edge of the semiconductor die from the supporting wafer by performing circular arc exercise on the semiconductor die by using the transfer unit at an angle of θ2 with respect to the first direction.

In some example embodiments, forming a semiconductor die on a supporting wafer may include forming a through-silicon via penetrating from a first surface of the semiconductor die to a second surface of the semiconductor die that faces the first surface.

In some example embodiments, forming the through-silicon via may include providing a silicon wafer; forming the through-silicon via, exposed to one surface of the silicon wafer, in the silicon wafer; attaching the supporting wafer to the one surface of the silicon wafer; and/or polishing another surface of the silicon wafer to expose the through-silicon via.

In some example embodiments, the semiconductor die may include multiple semiconductor dies, a gap between the multiple semiconductor dies may be greater than {(length of diagonal line−length of horizontal side)/2}, the length of diagonal line may be a length of a diagonal line on a vertical rectangular section of a given one of the multiple semiconductor dies, and/or the length of horizontal side may be a length of a horizontal side on a vertical rectangular section of the given one of the multiple semiconductor dies.

In some example embodiments, a fabricating method of a semiconductor device may include forming a first semiconductor device on a supporting wafer, the first semiconductor device including a first surface on a bottom of the first semiconductor device and a second surface on a top of the first semiconductor device; picking up the first semiconductor device from the supporting wafer by using a transfer unit while maintaining the first semiconductor device oriented so that the second surface faces upwardly; moving the first semiconductor device onto a second semiconductor device while maintaining the first semiconductor device oriented so that the second surface faces upwardly; and/or bonding the first semiconductor device to the second semiconductor device while maintaining the first semiconductor device oriented so that the second surface faces upwardly.

In some example embodiments, the transfer unit may include a head unit configured to enable twisting movement.

In some example embodiments, picking up the first semiconductor device may include separating an edge of the first semiconductor device from the supporting wafer based on twisting movement, and/or picking up the first semiconductor device by using the transfer unit.

In some example embodiments, performing the twisting movement may include performing circular arc exercise at an angle with respect to a direction from the transfer unit to the first semiconductor device, and/or the first semiconductor device may move according to the twisting movement.

In some example embodiments, forming the first semiconductor device may include forming a through-silicon via that penetrates the first surface and the second surface.

In some example embodiments, a pick-up apparatus may include a main body that includes a first axis extending in a first direction, a rotation driving unit rotating the first axis, an up-down driving unit moving the main body up and down, and/or a head unit connected to the first axis. The head unit may move in a direction in which the first axis rotates.

In some example embodiments, a first semiconductor device may have a first surface configured to attach to a supporting wafer and a second surface different from the first surface, the head unit may have a surface configured to attach to the second surface of the first semiconductor device, and/or the first semiconductor device may move in a direction in which the head unit rotates.

In some example embodiments, a fabricating method of a semiconductor device may include forming a first semiconductor device on a supporting wafer, attaching to the first semiconductor device a transfer unit configured to enable twisting movement, and/or performing the twisting movement to move the first semiconductor device.

In some example embodiments, the first semiconductor device may include a surface on a top of the first semiconductor device, and/or when attaching to the first semiconductor device a transfer unit configured to enable twisting movement, the first semiconductor device may be maintained in an orientation so that the surface faces upwardly.

In some example embodiments, the first semiconductor device may include a surface on a top of the first semiconductor device, and/or when performing the twisting movement to move the first semiconductor device, the first semiconductor device may be maintained in an orientation so that the surface faces upwardly.

In some example embodiments, the first semiconductor device may include a first surface and a second surface different from the first surface, and/or forming the first semiconductor device may include forming a through-silicon via that penetrates the first and second surfaces.

In some example embodiments, the twisting movement may separate an edge of the first semiconductor device from the supporting wafer.

In some example embodiments, the fabricating method may further include bonding the first semiconductor device to a second semiconductor device.

In some example embodiments, the first semiconductor device may include a surface on a top of the first semiconductor device, and/or when bonding the first semiconductor device to the second semiconductor device, the first semiconductor device may be maintained in an orientation so that the surface faces upwardly.

### BRIEF DESCRIPTION OF THE DRAWINGS

The above and/or other aspects and advantages will become more apparent and more readily appreciated from the following detailed description of example embodiments, taken in conjunction with the accompanying drawings, in which:

FIGS. 1 to 7 are cross-sectional views illustrating intermediate structures for explaining a fabricating method of a semiconductor device according to some example embodiments;

FIG. 8 is a plan view illustrating intermediate structures for explaining a fabricating method of a semiconductor device according to some example embodiments;

FIG. 9 is a cross-sectional view illustrating a transfer unit of FIG. 8;

FIGS. 10 to 13 are cross-sectional views illustrating intermediate structures for explain a fabricating method of a semiconductor device according to some example embodiments;

FIGS. 14 and 15 are cross-sectional views illustrating intermediate structures for explain a fabricating method of a semiconductor device according to some example embodiments;

FIG. 16 is a perspective view illustrating a pick-up apparatus of a semiconductor device according to some example embodiments;

FIG. 17 is a perspective view illustrating a pick-up apparatus of a semiconductor device according to some example embodiments; and

FIG. 18 is a perspective view illustrating a pick-up apparatus of a semiconductor device according to some example embodiments.

### DETAILED DESCRIPTION

Example embodiments will now be described more fully with reference to the accompanying drawings. Embodiments, however, may be embodied in many different forms and should not be construed as being limited to the embodiments set forth herein. Rather, these example embodiments are provided so that this disclosure will be thorough and complete, and will fully convey the scope to those skilled in the art. In the drawings, the thicknesses of layers and regions may be exaggerated for clarity.

It will be understood that when an element is referred to as being “on,” “connected to,” “electrically connected to,” or “coupled to” to another component, it may be directly on, connected to, electrically connected to, or coupled to the other component or intervening components may be present. In contrast, when a component is referred to as being “directly on,” “directly connected to,” “directly electrically connected to,” or “directly coupled to” another component, there are no intervening components present. As used herein, the term “and/or” includes any and all combinations of one or more of the associated listed items.

It will be understood that although the terms first, second, third, etc., may be used herein to describe various elements, components, regions, layers, and/or sections, these elements, components, regions, layers, and/or sections should not be limited by these terms. These terms are only used to distinguish one element, component, region, layer, and/or section from another element, component, region, layer, and/or section. For example, a first element, component, region, layer, and/or section could be termed a second element, component, region, layer, and/or section without departing from the teachings of example embodiments.

Spatially relative terms, such as “beneath,” “below,” “lower,” “above,” “upper,” and the like may be used herein for ease of description to describe the relationship of one component and/or feature to another component and/or feature, or other component(s) and/or feature(s), as illustrated in the drawings. It will be understood that the spatially relative terms are intended to encompass different orientations of the device in use or operation in addition to the orientation depicted in the figures.

The terminology used herein is for the purpose of describing particular example embodiments only and is not intended to be limiting of example embodiments. As used herein, the singular forms “a,” “an,” and “the” are intended to include the plural forms as well, unless the context clearly indicates otherwise. It will be further understood that the terms “comprises,” “comprising,” “includes,” and/or “including,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and should not be interpreted in an idealized or overly formal sense unless expressly so defined herein.

Reference will now be made to example embodiments, which are illustrated in the accompanying drawings, wherein like reference numerals may refer to like components throughout.

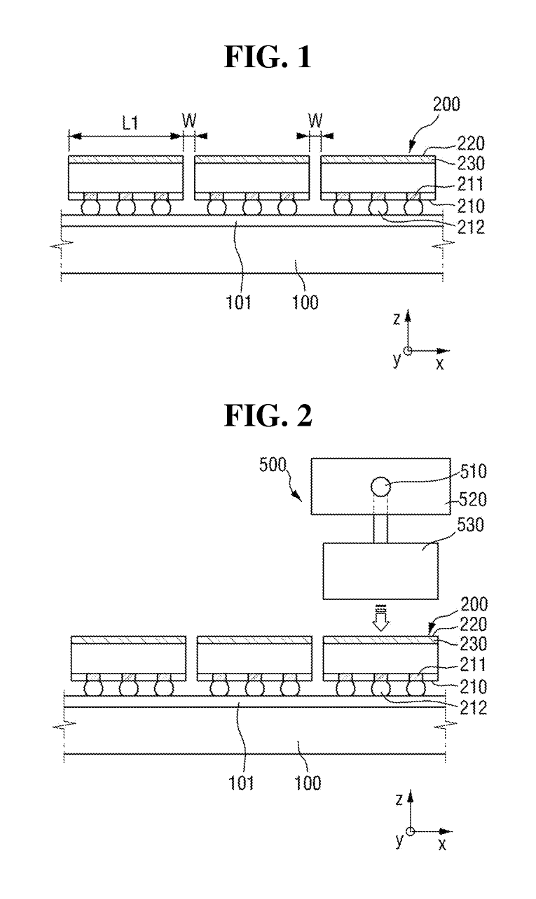

Hereinafter, a fabricating method of a semiconductor device according to some example embodiments will be described with reference to FIGS. 1 to 7. FIGS. 1 to 7 are cross-sectional views illustrating intermediate structures for explain a fabricating method of a semiconductor device according to some example embodiments.

First, referring to FIG. 1, a semiconductor die 200 is formed on a supporting wafer 100. In detail, a first connection pad 211 and a connection terminal 212 contacting the first connection pad 211 are formed on one surface of the semiconductor die 200, and a wiring layer 230 is formed on the other surface of the semiconductor die 200. FIG. 1 illustrates that the connection terminal 212 is a solder ball. Although not illustrated in detail, circuit patterns, etc. may be formed on the wiring layer 230. Next, the semiconductor die 200 is attached to one surface of the supporting wafer 100 by using the connection terminal 212 and is diced into a desired (or alternatively, predetermined) size to form a plurality of semiconductor dies 200. Accordingly, the plurality of semiconductor dies 200, which are spaced a desired (or alternatively, predetermined) distance (W) apart from each other and extend by a length L1, are formed. Each of the semiconductor dies 200 includes a pair of surfaces 210 and 220 facing each other. The first surface 210 faces the supporting wafer 100, and the second surface 220 opposite to the first surface 210 is exposed upwardly. In order to increase an adhesive force with the semiconductor dies 200, an adhesive layer 101 may be formed on one surface of the supporting wafer 100. However, the adhesive layer 101 may not be formed.

The semiconductor dies 200 may be formed of silicon, silicon-on-insulator (SOI), silicon germanium, or the like, but example embodiments are not limited thereto. Although not shown in detail, multiple wirings, multiple transistors, multiple passive elements, and so on, may be integrated into the semiconductor die 200. In addition, although not shown, the connection terminal 212 may also be formed on the second surface 220 of the semiconductor die 200. FIG. 1 illustrates that the connection terminal 212 is a solder ball, but example embodiments are not limited thereto. For example, the connection terminal 212 may be a conductive bump, a conductive spacer, a pin grid array (PGA), and so on.

Referring to FIG. 2, a transfer unit 500 enabling twisting movement is attached to the semiconductor die 200. In detail, the transfer unit 500 including a head unit 530 enabling twisting movement is attached to the second surface 220 exposed to a top portion of the semiconductor die 200. Although not shown in detail, the head unit 530, including a vacuum absorbing means, may be attached to the second surface 220 of the semiconductor die 200. Here, the twisting movement means that a position of the semiconductor die 200 is changed by performing circular arc exercise at a desired (or alternatively, predetermined) angle. For example, the head unit 530 may perform twisting movement by exercising in circular arcs in a first direction (X) or a second direction (Y) at a desired (or alternatively, predetermined) angle with respect to a third direction (Z). Alternatively, the head unit 530 may also perform twisting movement by exercising in circular arcs in the first direction (X) at a desired (or alternatively, predetermined) angle with respect to the second direction (Y). As the head unit 530 exercises in circular arcs, the semiconductor die 200 also exercises in circular arcs, so that it is twisted up and down and left and right. In more detail, when the head unit 530 performs twisting movement by exercising in circular arcs at a desired (or alternatively, predetermined) angle in the first direction (X) with respect to the third direction (Z), the semiconductor die 200 performs circular arc exercise, while reciprocating left and right at the desired (or alternatively, predetermined) angle in the first direction (X) with respect to the third direction (Z). In addition, when the head unit 530 performs twisting movement by exercising in circular arcs at a desired (or alternatively, predetermined) angle in the first direction (X) with respect to the second direction (Y), the semiconductor die 200 performs circular arc exercise, reciprocating left and right at the desired (or alternatively, predetermined) angle in the first direction (X) with respect to the second direction (Y). While FIG. 2 illustrates that the transfer unit 500 includes a main body 520 including a rotation axis 510 and a rotation axis 510 and the head unit 530 connected to the rotation axis 510, example embodiments do not limit the structure of the transfer unit 500 to that illustrated herein as long as the head unit 530 enables twisting movement.

An example structure of the transfer unit 500 that may be used in example embodiments will later be described.

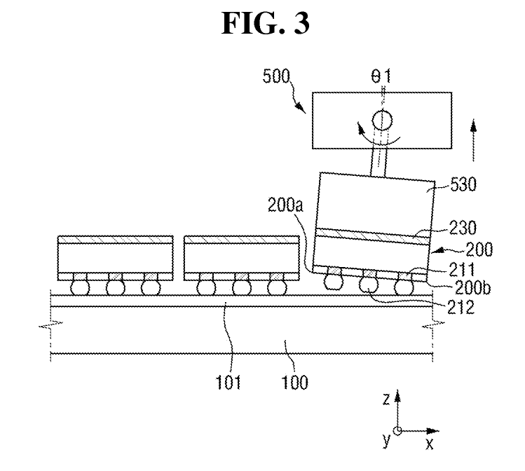

Next, referring to FIGS. 3 to 5, twisting movement is performed by using the transfer unit 500 attached to the second surface 220 of the semiconductor die 200, thereby picking up the semiconductor die 200 from the supporting wafer 100.

In detail, referring to FIG. 3, the head unit 530 of the transfer unit 500 performs twisting movement by exercising in circular arcs in the first direction (X) with respect to the third direction (Z), thereby moving the semiconductor die 200 accordingly.

That is to say, the head unit 530 exercises in circular arcs in the first direction (X) at a desired (or alternatively, predetermined angle) (θ1) with respect to the third direction (Z) perpendicular to the first direction (X), and the semiconductor die 200 attached to the head unit 530 also exercises in circular arcs while reciprocating in the first direction (X). As a result, while the semiconductor die 200 moves in the first direction (X), one side 200a of the semiconductor die 200 moves upwardly and the one side 200a of the semiconductor die 200 is separated from the supporting wafer 100. Here, in order to easily detach the semiconductor die 200 from the supporting wafer 100, the transfer unit 500 performs up-down movement while exercising in circular arcs.

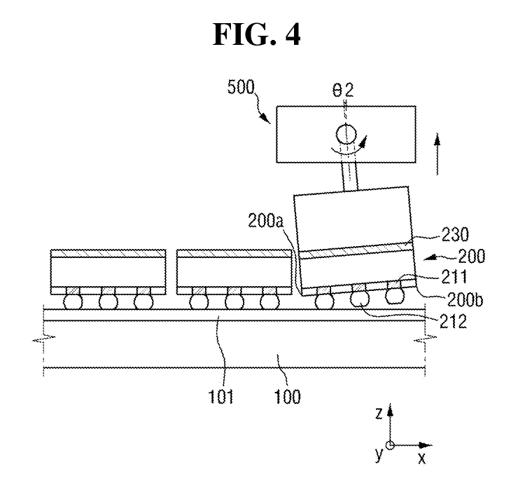

Referring to FIG. 4, in a manner similar to that shown in FIG. 3, the head unit 530 of the transfer unit 500 performs twisting movement by exercising in circular arcs in the first direction (X) at a desired (or alternatively, predetermined angle) (θ2) with respect to the third direction (Z). According to the twisting movement, the semiconductor die 200 attached to the head unit 530 of the transfer unit 500 is also shifted from its original position. That is to say, as the head unit 530 exercises in circular arcs, the semiconductor die 200 reciprocates in the first direction (X) at the desired (or alternatively, predetermined) angle (θ2). Accordingly, the other side 200b of the semiconductor die 200 moves upwardly and the other side 200b of the semiconductor die 200 is separated from the supporting wafer 100. Like in FIG. 3, in order to easily detach the semiconductor die 200 from the supporting wafer 100, the transfer unit 500 performs up-down movement while exercising in circular arcs.

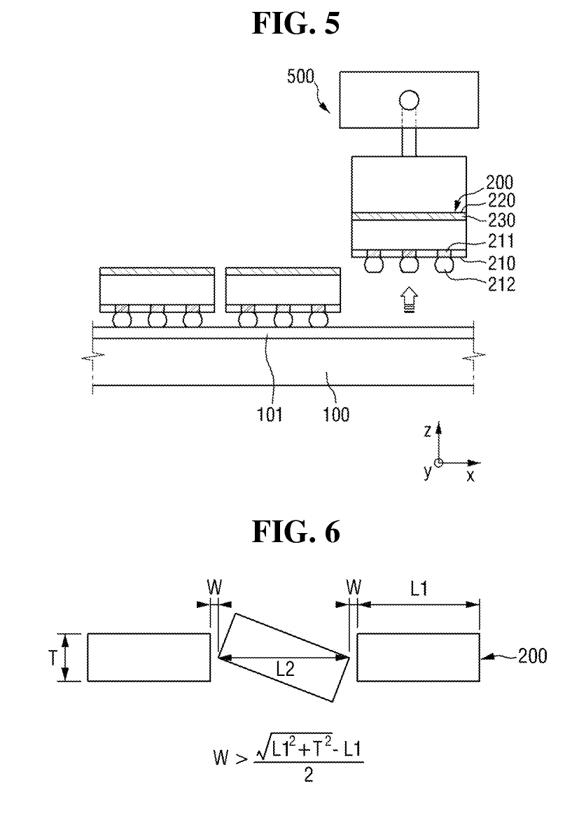

Continuously, referring to FIG. 5, the semiconductor die 200 having its edge separated from the supporting wafer 100 is picked up by using the transfer unit 500. As shown in FIGS. 3 and 4, since the edge of the semiconductor die 200 has already been separated from the supporting wafer 100 due to twisting movement of the head unit 530, the semiconductor die 200 can be easily separated and picked up from the supporting wafer 100 without the need of a push-up unit.

Here, a distance W between each of the plurality of semiconductor dies 200 should have a margin enough to avoid collision with the adjacent semiconductor die 200 when the semiconductor die 200 performs twisting movement. Referring to FIG. 6, the distance W between each of the plurality of semiconductor dies 200 should be greater than (L2−L1)/2 where L2 denotes a length of a diagonal line of the semiconductor die 200 and L1 denotes a length of a side in the first direction (X1) of the semiconductor die 200. Here, the length of a diagonal line of the semiconductor die 200 can be calculated by:

{(L1)²+(T)²}0.5

where L1 denotes a length of a side in the first direction (X1) of the semiconductor die 200 and T denotes a thickness of the semiconductor die 200. In addition, L2 denotes a length of a diagonal line on a vertical section of the semiconductor die 200.

In the fabricating method of the semiconductor device according to some example embodiments, the semiconductor die 200 can be easily picked up from the supporting wafer 100 by using the transfer unit 500 including the head unit 530 enabling twisting movement.

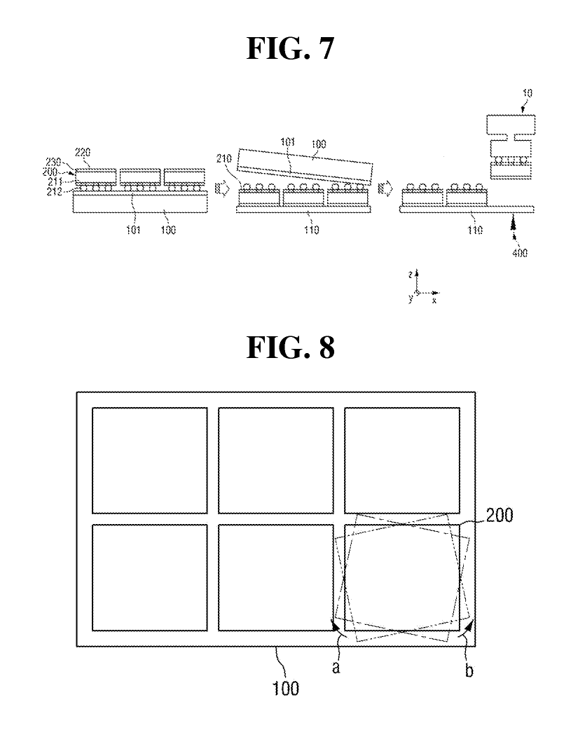

Referring to FIG. 7, when a transfer unit 10 disables twisting movement, the semiconductor die 200 is not easily detached from the supporting wafer 100. Thus, after the supporting wafer 100 is first removed from the semiconductor die 200, a fixing tape 110 is attached to the second surface 220 of the semiconductor die 200 to then pick up from the semiconductor die 200 from the fixing tape 110. Here, a push-up unit 400, e.g., a pick-up pin, is used in easily separating the semiconductor die 200 from the fixing tape 110. However, in the fabricating method of the semiconductor device according to some example embodiments, since the edge of the semiconductor die 200 is first separated from the supporting wafer 100 by using the transfer unit 500 including the head unit 530 enabling twisting movement, the semiconductor die can be easily picked up directly from the supporting wafer 100. Therefore, the fabricating method of the semiconductor device according to some example embodiments does not require a process of removing a supporting wafer in advance.

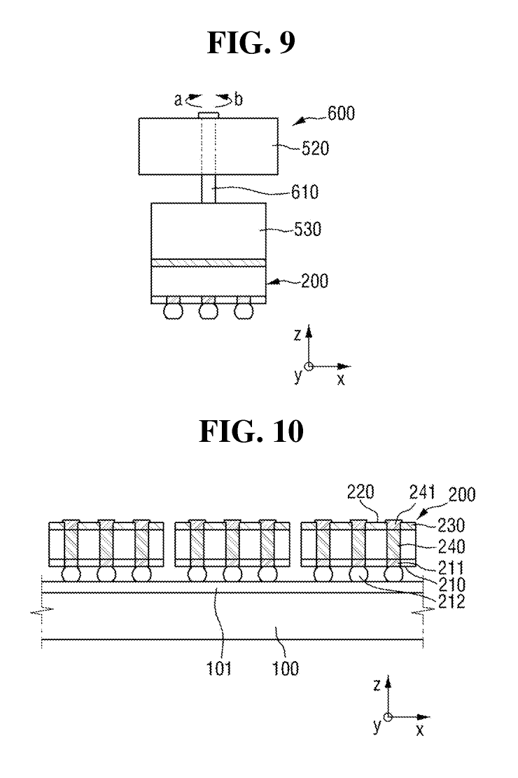

Hereinafter, a fabricating method of a semiconductor device according to some example embodiments will be described with reference to FIGS. 8 and 9. FIG. 8 is a plan view illustrating intermediate structures for explain a fabricating method of a semiconductor device according to some example embodiments, and FIG. 9 is a cross-sectional view illustrating a transfer unit of FIG. 8. Here, substantially the same components as those of the fabricating method of the semiconductor device according to some example embodiments are denoted by the same reference numerals and detailed descriptions thereof will be omitted. The fabricating method of the semiconductor device according to some example embodiments may be different from the fabricating method of the semiconductor device according to some example embodiments in view of twisting movement corresponding to steps shown in FIGS. 3 and 4 and the following description will focus on the difference.

Referring to FIGS. 8 and 9, an edge of the semiconductor die 200 is separated from a supporting wafer 100 by the supporting wafer 100 exercising in circular arcs by using a transfer unit 600 including a head unit 530 enabling twisting movement. In detail, the head unit 530 performs twisting movement by exercising in circular arcs in the first direction (X) at a desired (or alternatively, predetermined) angle with respect to the second direction (Y). Due to the twisting movement, the semiconductor die 200 reciprocates while exercising in circular arcs in the first direction (X) at a desired (or alternatively, predetermined) angle with respect to the second direction (Y). That is to say, the semiconductor die 200 reciprocate on a plane parallel with the supporting wafer 100 in the first direction (X) and in the ‘a’ or ‘b’ direction. Accordingly, an edge of the semiconductor die 200 can be separated from the supporting wafer 100. Referring to FIG. 9, the transfer unit 600 performing twisting movement includes a rotation axis 610, a main body 520, and a head unit 530. Since the rotation axis 610 is connected to the head unit 530 from the main body 520, as the rotation axis 610 exercises in circular arcs, the head unit 530 also exercises in circular arcs. Here, the rotation axis 610 is disposed at a desired (or alternatively, predetermined) angle in the first direction (X) with respect to the second direction (Y) and exercises in circular arcs in the ‘a’ or ‘b’ direction, which will later be described in more detail.

Hereinafter, a fabricating method of a semiconductor device according to some example embodiments will be described with reference to FIGS. 10 to 13. FIGS. 10 to 13 are cross-sectional views illustrating intermediate structures for explain a fabricating method of a semiconductor device according to some example embodiments. Here, substantially the same components as those of the fabricating method of the semiconductor device according to some example embodiments are denoted by the same reference numerals and detailed descriptions thereof will be omitted. The fabricating method of the semiconductor device according to some example embodiments may be different from the fabricating method of the semiconductor device according to some example embodiments in that a through-silicon via (TSV) is formed in a semiconductor die and the following description will focus on the difference.

Referring to FIG. 10, a TSV 240 penetrating a first surface 210 and a second surface 220 is formed in each of the semiconductor dies 200, and a second connection pad 241 contacting the TSV 240 is formed on the second surface 220.

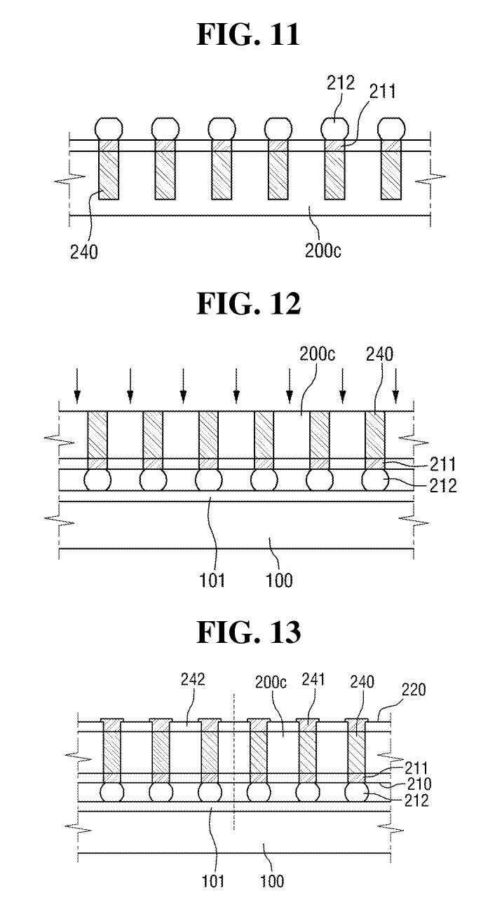

In detail, referring to FIG. 11, the TSV 240 is formed into a silicon wafer 200c from one surface thereof, and a first connection pad 211 and a connection terminal 212 connected to the TSV 240 are formed the one surface. Specifically, a throughhole is formed in the silicon wafer 200c by photolithography process, and the throughhole is filled with a conductive material to form the TSV 240, followed by forming the first connection pad 211 and the connection terminal 212 on the one surface exposing the TSV 240. Here, the TSV 240 is exposed to one surface of the silicon wafer 200c, but not exposed to the other surface thereof.

Next, referring to FIG. 12, the supporting wafer 100 is attached to one surface of the silicon wafer 200c and the other surface of the silicon wafer 200c is polished to expose the TSV 240. In detail, the supporting wafer 100 is attached to one surface of the silicon wafer 200c by using the connection terminal 212 and the adhesive layer 101, and the other surface of the silicon wafer 200c is polished by, for example, chemical mechanical polishing (CMP) until the TSV 240 is exposed. Through the aforementioned process, the through-silicon via (TSV) is formed, the through-silicon via (TSV) penetrating the one and other surfaces of the silicon wafer 200c.

Referring to FIGS. 10 and 13, the second connection pad 241 contacting the TSV 240 is formed on the other surface of the silicon wafer 200c, through which the TSV 240 is exposed, and the silicon wafer 200c is diced to form a plurality of semiconductor dies 200. In detail, a passivation layer 242 is formed on the other surface of the silicon wafer 200c, through which the TSV 240 is exposed, and a contact hole exposing the TSV 240 is formed in the passivation layer 242, and a second connection pad 241 electrically connected to the TSV 240 is formed on the passivation layer 242 by filling the contact hole with a conductive material.

As described above, in order to form the through-silicon via (TSV), it is necessary to process the other surface of the silicon wafer. Here, in order to safely treat the silicon wafer that is thinned in the course of processing of the silicon wafer, a supporting wafer is required.

In the fabricating method of the semiconductor device according to some example embodiments, when the through-silicon via (TSV) is formed by using the supporting wafer in the aforementioned manner, a process of removing the supporting wafer is not required and a semiconductor die can be directly picked up from the supporting wafer, thereby simplifying the fabricating process.

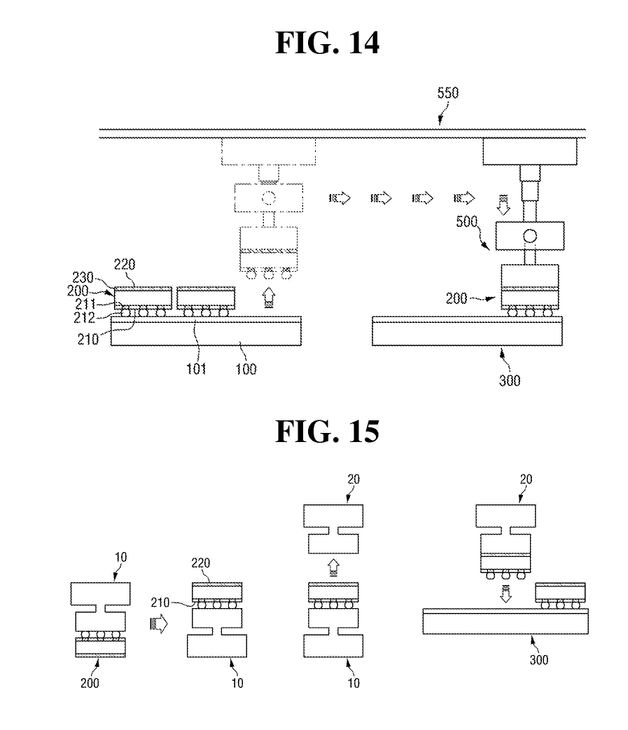

Hereinafter, a fabricating method of a semiconductor device according to some example embodiments will be described with reference to FIGS. 14 and 15. FIGS. 14 and 15 are cross-sectional views illustrating intermediate structures for explain a fabricating method of a semiconductor device according to some example embodiments. The fabricating method of the semiconductor device according to some example embodiments may be different from the fabricating method of the semiconductor device according to some example embodiments in that picking-up, transferring and bonding of the semiconductor die are performed by using only a transfer unit including a head unit enabling twisting movement. Here, the transfer unit 500 further includes a carrier unit 550. The following description will focus on the transfer unit 500 further including the carrier unit 550.

Referring to FIG. 14, a semiconductor die 200 picked up from the supporting wafer 100, as shown in FIG. 5, is transferred to a second semiconductor device 300 by using the transfer unit 500, and the transferred semiconductor die 200 is bonded to the second semiconductor device 300. In detail, the transfer unit 500 is attached to a second surface 220 positioned on the semiconductor die 200, the semiconductor die 200 is picked up from the supporting wafer 100 by using the transfer unit 500, and the semiconductor die 200 is then transferred to the second semiconductor device 300 while the semiconductor die 200 is maintained at a position at which the second surface 220 faces upwardly. Next, the semiconductor die 200 is bonded to the second semiconductor device 300 by using a connection terminal 212. Although not shown in detail, a pressing means or a heating means is provided in a head unit 530 of the transfer unit 500, thereby allowing the transfer unit 500 to be easily attached to the second semiconductor device 300. In addition, although not shown in detail, in order to facilitate attachment, a connection terminal may be formed one surface of the second semiconductor device 300.

Here, the transfer unit 500 further includes a carrier unit 550 enabling linear movement. The carrier unit 550 connected to the transfer unit 500 carries the transfer unit 500.

Referring to FIGS. 7 and 15, when the supporting wafer 100 is removed and the semiconductor die 200 is picked up from a fixing tape 110, the transfer unit 10 is attached to the first surface 210 of the semiconductor die 200 on the supporting wafer 100, the first surface 210 facing the supporting wafer 100, rather than the second surface 220 exposed to the upper portion of the semiconductor die 200. Therefore, after the semiconductor die 200 is carried and before it is bonded to the second semiconductor device 300 or before the semiconductor die 200 is carried, it is necessary to transfer again the semiconductor die 200 attached to the transfer unit 10 to a bonding head 20. That is to say, after the semiconductor die 200 is picked up by the transfer unit 10 and is again transferred to the bonding head 20 to then be bonded to the second semiconductor device 300 by the bonding head 20. However, in the fabricating method of the semiconductor device according to some example embodiments, the semiconductor die 200 is directly picked up and transferred from the supporting wafer 100 by using the transfer unit 500, it is directly bonded by the transfer unit 500 without having to move the same to the bonding head 20. That is to say, while the semiconductor die 200 is picked up, transferred and bonded, the direction of the semiconductor die 200 is maintained without being changed and the picking up, transferring and bonding operations are all performed by using only the transfer unit 500, thereby simplifying the fabricating process.

The semiconductor die 200 according to some example embodiments may be a semiconductor chip, and a multichip package having a plurality semiconductor chips stacked may be formed using the above-described methods according to some example embodiments. Here, each of the semiconductor chips, including a through-silicon via (TSV), may achieve chip-level stacking. In addition, the fabricating methods of semiconductor devices according to example embodiments are not limited to picking up a semiconductor die, but may also be applied to picking up a semiconductor device of a semiconductor package. For example, a package on package having a plurality of semiconductor packages can be fabricated by picking up, carrying and bonding the semiconductor packages using the above-described methods according to some example embodiments.

Hereinafter, a pick-up apparatus of a semiconductor device, which can be applied as a transfer unit in the fabricating methods of semiconductor devices according to some example embodiments will be described with reference to FIGS. 14 and 16 to 18.

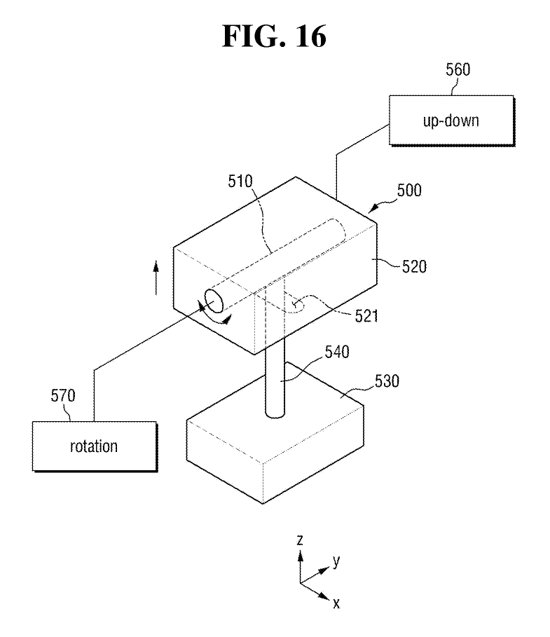

First, a pick-up apparatus of a semiconductor device according to some example embodiments will be described with reference to FIGS. 14 and 16. FIG. 16 is a perspective view illustrating a pick-up apparatus of a semiconductor device according to some example embodiments.

Referring to FIGS. 14 and 16, the transfer unit 500 of a semiconductor device according to some example embodiments includes a rotation axis 510, a main body 520, and a head unit 530. The transfer unit 500 may further include a connection unit 540, a carrier unit 550, an up-down driving unit 560 and a rotation driving unit 570.

The rotation axis 510 enables rotation movement and also exercises in circular arcs by rotating at a desired (or alternatively, predetermined) angle. That is to say, rotation movement is performed at a desired (or alternatively, predetermined) angle only in a direction perpendicular to the rotation axis 510, thereby enabling circular arc exercise. The rotation axis 510 extends in the second direction (Y), and the main body 520 includes the rotation axis 510.

The rotation axis 510 is connected to the rotation driving unit 570. Specifically, the rotation driving unit 570 may be a step motor, but example embodiments are not limited thereto. While FIG. 16 shows that the rotation driving unit 570 is disposed outside the main body 520, the rotation driving unit 570 may be incorporated into the main body 520.

The main body 520 includes the rotation axis 510 and is connected to the carrier unit 550, as shown in FIG. 14. An opening 521 is formed on a bottom surface of the main body 520 to allow the connection unit 540 vertically extending from the rotation axis 510 to protrude from the main body 520 to then move. In addition, the up-down driving unit 560 is connected to the main body 520 to adjust up-down movement of the main body 520. Here, as the main body 520 moves up and down, the rotation axis 510 incorporated into the main body 520 and the head unit 530 connected thereto also move up and down accordingly. The up-down driving unit 560 may be an actuator, but example embodiments are not limited thereto.

The head unit 530 is connected to the rotation axis 510 by the connection unit 540 and is directly attached to a semiconductor device to pick up the semiconductor device. The head unit 530 is coupled to an end of the connection unit 540 vertically extending from the rotation axis 510. The rotation axis 510, the connection unit 540 and the head unit 530 may be integrally formed with each other. Since the head unit 530 is connected to the rotation axis 510, it moves in the direction in which the rotation axis 510 moves. Although not shown in detail, the head unit 530 may include a vacuum absorbing means to be attached to the semiconductor device, a pressing means or a heating means used to bond the semiconductor device.

Referring to FIG. 14, the carrier unit 550 is connected to the main body 520 and enables linear movement to move the transfer unit 500. As the transfer unit 500 moves, the semiconductor device attached to the head unit 530 of the transfer unit 500 also moves. FIG. 14 shows that the carrier unit 550 is of a cylinder type, but example embodiments are not limited thereto. The transfer unit 500 according to some example embodiments performs not only a picking-up operation but also a carrying operation by using the carrier unit 550.

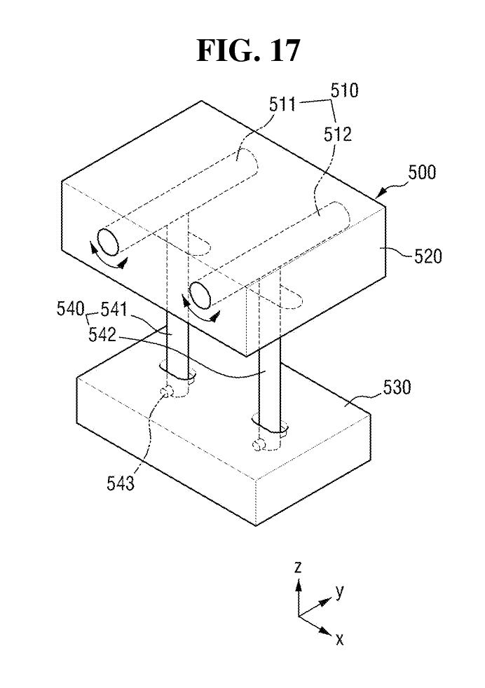

Hereinafter, a transfer unit of a semiconductor device according to some example embodiments will be described with reference to FIG. 17. FIG. 17 is a perspective view illustrating a transfer unit of a semiconductor device according to some example embodiments. Here, substantially the same components as those of the semiconductor device according to some example embodiments are denoted by the same reference numerals and detailed descriptions thereof will be omitted. The semiconductor device according to some example embodiments is different from the semiconductor device according to some example embodiments in that the pick-up apparatus according to some example embodiments includes two rotation axes and the following description will focus on the difference.

Referring to FIG. 17, the transfer unit 500 according to some example embodiments includes a rotation axis 510, a main body 520 and a head unit 530. The rotation axis 510 includes a first rotation axis 511 and a second rotation axis 512. In addition, the connection unit 540 includes a first connection unit 541, a second connection unit 542, and a hinge unit 543.

The rotation axis 510 includes a first rotation axis 511 and a second rotation axis 512 extending in a second direction (Y), and the first rotation axis 511 and the second rotation axis 512 are spaced a desired (or alternatively, predetermined) distance apart from each other. In detail, the first rotation axis 511 and the second rotation axis 512 are positioned to be close to different sides of main body 520. Although not shown, each of the first rotation axis 511 and the second rotation axis 512 are connected to a rotation driving unit and performs rotation movement or exercises in circular arcs by rotating only at a desired (or alternatively, predetermined) angle with respect to a direction perpendicular to the rotation axis 510.

The connection unit 540 includes a first connection unit 541 vertically extending from the first rotation axis 511, and a second connection unit 542 vertically extending from the second rotation axis 512. The first connection unit 541 and the second connection unit 542 connect the rotation axis 510 to the head unit 530, and are connected to the head unit 530 by the hinge unit 543 to allow the head unit 530 to move according to movement of the rotation axis 510. In order to allow the connection unit 540 to move smoothly, a groove into which the connection unit 540 is inserted may be formed on a top surface of the head unit 530. The shape of the hinge unit 543 is not limited to that shown in FIG. 17. Example embodiments do not limit the shape of the hinge unit 543 as long as the head unit 530 can move according to rotation of the rotation axis 510.

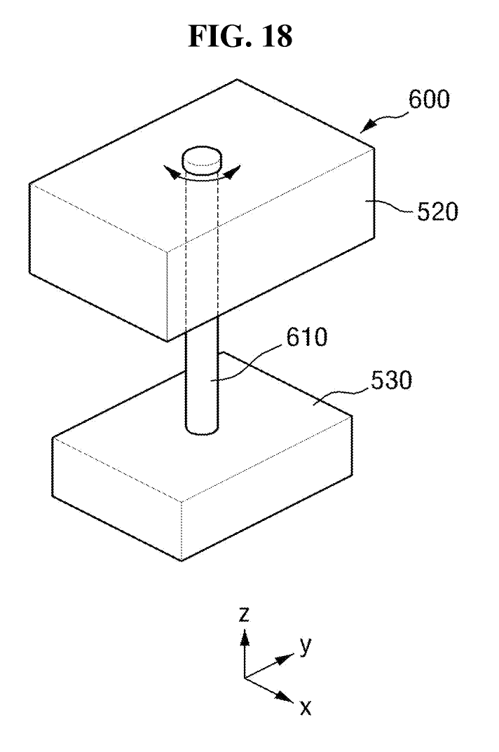

Hereinafter, a pick-up apparatus of a semiconductor device according to some example embodiments will be described with reference to FIG. 18. FIG. 18 is a perspective view illustrating a pick-up apparatus of a semiconductor device according to some example embodiments. Here, substantially the same components as those of the pick-up apparatus according to some example embodiments are denoted by the same reference numerals and detailed descriptions thereof will be omitted. The pick-up apparatus according to some example embodiments is different from the pick-up apparatus according to some example embodiments in that a rotation axis extends in a third direction (Z) and the following description will focus on the difference.

Referring to FIG. 18, the transfer unit 600 of a semiconductor device according to some example embodiments includes a rotation axis 610, a main body 520 and a head unit 530.

The rotation axis 610 extends in the third direction (Z) and is connected to the head unit 530. Although not shown in detail, the rotation axis 610 is connected to a rotation driving unit and performs rotation movement or exercises in circular arcs by rotating only at a desired (or alternatively, predetermined) angle with respect to a direction perpendicular to the rotation axis 610. The rotation axis 610 is connected to the head unit 530 while penetrating the main body 520.

The head unit 530 is coupled to an end of the rotation axis 610 and moves in a direction in which the rotation axis 610 moves. In detail, when the rotation axis 610 exercises in circular arcs at a desired (or alternatively, predetermined) angle with respect to a direction perpendicular to the rotation axis 610, the head unit 530 also exercises in circular arcs.

In the transfer units 500 and 600 of semiconductor devices according to some example embodiments, the head unit 530 is connected to the rotation axes 510 and 610, respectively, thereby enabling circular arc exercise. The circular arc exercise become twisting movement. The twisting movement of the head unit 530 is performed to facilitate separation of the semiconductor device attached to the head unit 530 from an object to which the semiconductor device is attached. That is to say, the semiconductor device is detached and attached from the edge based on twisting movement of the head unit 530, thereby facilitating a picking-up operation of the semiconductor device. In addition, the pick-up apparatus includes a carrier unit. In addition, picking-up, carrying and bonding operations of the semiconductor device can be continuously performed using only the pick-up apparatuses according to some example embodiments.

While example embodiments have been particularly shown and described, it will be understood by those of ordinary skill in the art that various changes in form and details may be made therein without departing from the spirit and scope of the present invention as defined by the following claims.

1. A fabricating method of a semiconductor device, the fabricating method comprising:
forming a semiconductor die on a supporting wafer; and
picking up the semiconductor die from the supporting wafer by attaching to the semiconductor die a transfer unit, the transfer unit including a head unit configured to enable twisting movement, and then performing the twisting movement.

2. The fabricating method of claim 1, wherein after the semiconductor die is picked up from the supporting wafer, the semiconductor die is moved to a top portion of a first semiconductor device by using the twisting movement, and the semiconductor die is bonded to the first semiconductor device.

3. The fabricating method of claim 1, wherein the twisting movement comprises:
performing circular arc exercise on the semiconductor die by using the transfer unit.

4. The fabricating method of claim 3, wherein picking up the semiconductor die from the supporting wafer comprises:
picking up the semiconductor die by using the transfer unit after separating an edge of the semiconductor die from the supporting wafer by performing circular arc exercise on the semiconductor die.

5. The fabricating method of claim 3, wherein the twisting movement further comprises:
separating one edge of the semiconductor die from the supporting wafer by performing circular arc exercise on the semiconductor die by using the transfer unit at an angle of θ1 with respect to a first direction perpendicular to a second direction from the transfer unit to the semiconductor die; and
separating another edge of the semiconductor die from the supporting wafer by performing circular arc exercise on the semiconductor die by using the transfer unit at an angle of θ2 with respect to the first direction.

6. The fabricating method of claim 1, wherein forming a semiconductor die on a supporting wafer comprises:
forming a through-silicon via penetrating from a first surface of the semiconductor die to a second surface of the semiconductor die that faces the first surface.

7. The fabricating method of claim 6, wherein forming the through-silicon via comprises:
providing a silicon wafer;
forming the through-silicon via, exposed to one surface of the silicon wafer, in the silicon wafer;
attaching the supporting wafer to the one surface of the silicon wafer; and
polishing another surface of the silicon wafer to expose the through-silicon via.

8. The fabricating method of claim 1, wherein the semiconductor die includes multiple semiconductor dies,
wherein a gap between the multiple semiconductor dies is greater than {(length of diagonal line−length of horizontal side)/2},
wherein the length of diagonal line is a length of a diagonal line on a vertical rectangular section of a given one of the multiple semiconductor dies, and
wherein the length of horizontal side is a length of a horizontal side on a vertical rectangular section of the given one of the multiple semiconductor dies.

9. A fabricating method of a semiconductor device, the fabricating method comprising:
forming a first semiconductor device on a supporting wafer, the first semiconductor device including a first surface on a bottom of the first semiconductor device and a second surface on a top of the first semiconductor device;
picking up the first semiconductor device from the supporting wafer by using a transfer unit while maintaining the first semiconductor device oriented so that the second surface faces upwardly;
moving the first semiconductor device onto a second semiconductor device while maintaining the first semiconductor device oriented so that the second surface faces upwardly; and
bonding the first semiconductor device to the second semiconductor device while maintaining the first semiconductor device oriented so that the second surface faces upwardly.

10. The fabricating method of claim 9, wherein the transfer unit includes a head unit configured to enable twisting movement.

11. The fabricating method of claim 10, wherein picking up the first semiconductor device comprises:
separating an edge of the first semiconductor device from the supporting wafer based on twisting movement; and
picking up the first semiconductor device by using the transfer unit.

12. The fabricating method of claim 11, wherein performing the twisting movement includes performing circular arc exercise at an angle with respect to a direction from the transfer unit to the first semiconductor device, and
wherein the first semiconductor device moves according to the twisting movement.

13. The fabricating method of claim 9, wherein forming the first semiconductor device comprises:
forming a through-silicon via that penetrates the first surface and the second surface.

14.-15. (canceled)

16. A fabricating method of a semiconductor device, the fabricating method comprising:
forming a first semiconductor device on a supporting wafer;
attaching to the first semiconductor device a transfer unit configured to enable twisting movement; and
performing the twisting movement to move the first semiconductor device.

17. The fabricating method of claim 16, wherein the first semiconductor device includes a surface on a top of the first semiconductor device, and
wherein when attaching to the first semiconductor device a transfer unit configured to enable twisting movement, the first semiconductor device is maintained in an orientation so that the surface faces upwardly.

18. The fabricating method of claim 16, wherein the first semiconductor device includes a surface on a top of the first semiconductor device, and
wherein when performing the twisting movement to move the first semiconductor device, the first semiconductor device is maintained in an orientation so that the surface faces upwardly.

19. The fabricating method of claim 16, wherein the first semiconductor device includes a first surface and a second surface different from the first surface, and
wherein forming the first semiconductor device includes forming a through-silicon via that penetrates the first and second surfaces.

20. The fabricating method of claim 16, wherein the twisting movement separates an edge of the first semiconductor device from the supporting wafer.

21. The fabricating method of claim 16, further comprising:
bonding the first semiconductor device to a second semiconductor device.

22. The fabricating method of claim 21, wherein the first semiconductor device includes a surface on a top of the first semiconductor device, and
wherein when bonding the first semiconductor device to the second semiconductor device, the first semiconductor device is maintained in an orientation so that the surface faces upwardly.
